(19) United States
(12) Patent Application Publication
(10) Pub. No.: US 2023/0096330 A1
(43) Pub. Date: Mar. 30, 2023

(54) APPARATUS FOR PARTICLE MONITORING IN THE CHEMICAL LIQUID AND THE METHOD THEREOF

(71) Applicant: SEMICON TECH GLOBAL LIMITED, Seongnam-si, Gyeonggi-do (KR)

(72) Inventors: Soon Suk HONG, Seongnam-si, Gyeonggido (KR); Myung Hwan HWANG, Hwaseong-si, Gyeonggi-do (KR); Se Hyun JANG, Yongin-si, Gyeonggi-do (KR)

(73) Assignee: SEMICON TECH GLOBAL LIMITED, Seongnam-si, Gyeonggi-do (KR)

(21) Appl. No.: 16/975,395

(22) PCT Filed: Jul. 3, 2020
(86) PCT No.: PCT/KR2020/008732

§ 371 Date: Aug. 25, 2020

(30) Foreign Application Priority Data
Jul. 9, 2019 (KR) 10-2019-0082382

(51) Int. Cl. G01N 15/06; G03F 7/20

(52) U.S. Cl. CPC G01N 15/06; G03F 7/70608; G01N 2015/0693

(57) ABSTRACT

An apparatus for monitoring particles in a chemical solution includes a chemical solution supply device that stores a chemical solution and supplies the chemical solution according to a work start signal of a control unit, a first supply channel that is connected with the chemical solution supply device to supply the chemical solution, a filter that is connected with the first supply channel to purify the chemical solution, a branch channel and a main channel that are branched from the filter, a drain valve that is connected with the branch channel to open and close the branch channel, a particle monitor that is connected with the main channel to detect the amount of particles in the chemical solution, and a dispenser unit that receives the chemical solution from the particle monitor to supply the chemical solution to an object to be worked.

### TECHNICAL FIELD

The present invention relates to an apparatus and a method for monitoring particles in a chemical solution and more particularly, to an apparatus and a method capable of preventing an object to be worked such as a wafer from being contaminated by a chemical solution containing particles by checking a particle content in the chemical solution to be supplied to the object to be worked such as a wafer in real time and draining the corresponding chemical solution when the particle content in the chemical solution is greater than a reference value.

### BACKGROUND ART

In general, photolithography is used as a method for forming a circuit pattern on a wafer for manufacturing a semiconductor. The photolithography is a method of forming a circuit in the same manner as coating a photoresist having photosensitive properties thinly on a semiconductor wafer, and then placing a desired mask pattern, and irradiating light to take a picture.

Such photolithography is largely configured by a PR coating step of forming a photoresist (PR) layer by coating a photoresist on a wafer, an exposure step of developing a circuit pattern by irradiating light through a mask with a circuit pattern formed on the PR layer coated on the wafer, and an etching step of forming a desired pattern on the semiconductor wafer by removing the photoresist pattern by a drying or wetting method.

Meanwhile, in the coating step, a photoresist or a developer is coated on a wafer for manufacturing the semiconductor, and when particles are present in the photoresist or the developer, the entire wafer may be damaged.

Therefore, in the related art, the particles in the chemical solution was intended to be removed by using a filter, but nevertheless, a problem that the entire wafer could not be used was frequently caused by particles that were not partially removed.

On the other hand, the photolithography of coating the photoresistor is used even in not only a semiconductor manufacturing process but also a process for manufacturing a thin film transistor liquid crystal display (TFT LCD), and compared with the semiconductor manufacturing process, there is only a difference in that an object to be coated (that is, an object to which the chemical solution is coated) is not a wafer but glass, and the photolithography is substantially the same. Therefore, even in the TFT LCD manufacturing process, there are the same or similar problems caused by particles mixed in the above-described chemical solution, which are the same even in a process for manufacturing a printed circuit board (PCB) including a process of coating photosensitive ink, a process for manufacturing a light emitted diode (LED), etc.

Accordingly, in a process of coating a chemical solution such as a photoresist, a developer, photoresist ink, a glass resin, polyimide, and the like, a system of detecting the particles in the chemical solution and preventing damage to the wafer by the chemical solution containing the particles to perform continuously a process needs to be developed.

### DISCLOSURE

### Technical Problem

The present invention is to solve the conventional problems as described above, and an object of the present invention is to provide an apparatus and a method for monitoring particles in a chemical solution used in a processing apparatus of a semiconductor and the like.

The objects of the present invention are not limited thereto, and other objects, which are not mentioned above, will be apparently understood to those skilled in the art from the following description.

### Technical Solution

According to an embodiment of the present invention, an apparatus for monitoring particles in a chemical solution comprises a chemical solution supply device that stores a chemical solution and supplies the chemical solution according to a work start signal of a control unit, a first supply channel that is connected with the chemical solution supply device and supplied with the chemical solution, a filter that is connected with the first supply channel to purify the chemical solution, a branch channel and a main channel that are branched from the filter, a drain valve that is connected with the branch channel to open and close the branch channel, a particle monitor that is connected with the main channel to detect the amount of particles in the chemical solution, and a dispenser unit that receives the chemical solution from the particle monitor to supply the chemical solution to an object to be worked, wherein the particle monitor and the dispenser unit are connected to a second supply channel, and a control valve that controls the supply of the chemical solution to be supplied from the particle monitor to the dispenser unit is included in the second supply channel.

The control valve may block or allow the supply of the chemical solution to be supplied from the particle monitor to the dispenser unit.

For example, when the drain valve is opened, the control valve may be closed, and when the drain valve is in a closed state, the control valve may be maintained in an opened state.

The dispenser unit may be selectively movable to a home position which is located on one side of the object to be worked and does not supply the chemical solution to the object to be worked and an operation position which is located on the upper portion of the object to be worked to supply the chemical solution to the object to be worked.

Meanwhile, when a measurement value of the particle monitor is greater than or equal to a preset reference value, the drain valve may be opened and the control valve may be closed.

Further, after the chemical solution is drained to the outside through the opened drain valve for a predetermined time, the drain valve may be closed and the control valve may be opened, and the dispenser unit may move to the home position, and the chemical solution supplied to the dispenser unit may be drained for a predetermined time.

While the chemical solution is drained through the dispenser unit, when the measurement value of the particle monitor is less than or equal to a reference value, the dispenser unit may be moved to the operation position.

According to an embodiment of the present invention, a method for monitoring particles in a chemical solution relates to a method for monitoring particles in a chemical solution using the apparatus for monitoring the particles described above and comprises a first step of supplying a chemical solution from the chemical solution supply device while a drain valve is closed and a control valve is opened, a second step of comparing a measurement value measured from the particle monitor with a preset reference value, a third step of opening the drain valve, closing the control valve, and moving the dispenser unit to a home position when the measurement value is greater than the reference value, a fourth step of draining the chemical solution through the drain valve for a predetermined time, a fifth step of closing the drain valve and opening the control valve after the predetermined time, a sixth step of maintaining the dispenser unit in the home position, a seventh step of draining the chemical solution through the dispenser unit for a predetermined time, and an eighth step of performing a process by moving the dispenser unit to an operation position when the measurement value of the particle monitor is maintained less than or equal to the reference value while the seventh step is performed, wherein in the seventh step or the eighth step, when the measurement value of the particle monitor is greater than the reference value, a next step is performed sequentially from the first step again.

### Advantageous Effects

The apparatus and the method for monitoring the particles in the chemical solution according to the present invention have the following effects.

First, it is possible to prevent damage to the wafer by the particles contained in the chemical solution.

In the apparatus for monitoring the particles in the chemical solution according to the present invention, it is possible to fundamentally prevent the damage to the wafer by the contaminated chemical solution by monitoring the particles in the chemical solution before the processing of the wafer and draining the corresponding chemical solution for a predetermined time when there is abnormality.

Second, the process may proceed quickly without interruption.

The apparatus and the method for monitoring the particles in the chemical solution according to the present invention have advantages of automatically discharging the contaminated chemical solution and continuously performing the process even without worker's intervention by monitoring the chemical solution in real time, and then draining the chemical solution when the particles are mixed in the chemical solution and performing a normal process again when there is no abnormality in the chemical solution.

As described above, the present invention has an effect capable of performing a continuous process without interruption of the process while preventing the damage to the wafer caused by the particles by monitoring the particles mixed in the chemical solution in real time.

The effects of the present invention are not limited to the aforementioned effects, and other effects, which are not mentioned above, will be apparently understood to those skilled in the art from the description of the appended claims.

### DESCRIPTION OF DRAWINGS

FIG. 1 is a block diagram illustrating a chemical solution supply device in the related art.

FIG. 2 is a block diagram illustrating a chemical solution supply device according to the present invention.

FIG. 3 is a flowchart illustrating a chemical solution supply method according to the present invention.

### BEST MODE

Hereinafter, the present invention will be described with reference to the accompanying drawings. In describing the embodiments, like names and like reference numerals are used with respect to like components and the resulting additional description will be omitted.

In addition, in the following description of the embodiments of the present invention, it will be disclosed in advance that components having the same function just use the same names and the same reference numerals, and are not substantially identical to those of the related art.

Terms used in the embodiments of the present invention are used only to describe specific embodiments, and are not intended to limit the present invention. A singular form may include a plural form unless otherwise clearly indicated in the context.

In the embodiments of the present invention, it should be understood that the term “comprising” or “having” indicates that a feature, a number, a step, an operation, a component, a part or a combination thereof described in the specification is present, but does not exclude a possibility of presence or addition of one or more other features, numbers, steps, operations, components, parts, or combinations thereof, in advance.

A flowchart of a process of processing a wafer using a chemical solution in the related art will be described in detail by using FIG. 1.

First, a control unit (not illustrated) transmits a supply signal of a chemical solution to a chemical solution supply device 10. In the chemical solution supply device 10, a pump for supplying the chemical solution may be provided or a pump may also be provided in a channel connected to the supply device.

With the start of the supply of the chemical solution by the supply device, the control unit moves a working nozzle 40 from a home position to an operation position.

In the home position, the nozzle is located on one side of the wafer so that the chemical solution is not delivered to the wafer, and the operation position is a position where the nozzle is located on the top of the wafer to supply the chemical solution to the wafer.

Thereafter, the chemical solution is supplied to the top of the wafer through the working nozzle 40 to perform a wafer processing operation.

A part of the solution supplied from the upper portion of the wafer is collected in a chamber 60, a drain channel is connected to the chamber 60, and the solution collected in the chamber 60 is drained through the channel.

Hereinafter, preferred embodiments of the present invention will be described in detail with reference to the accompanying drawings.

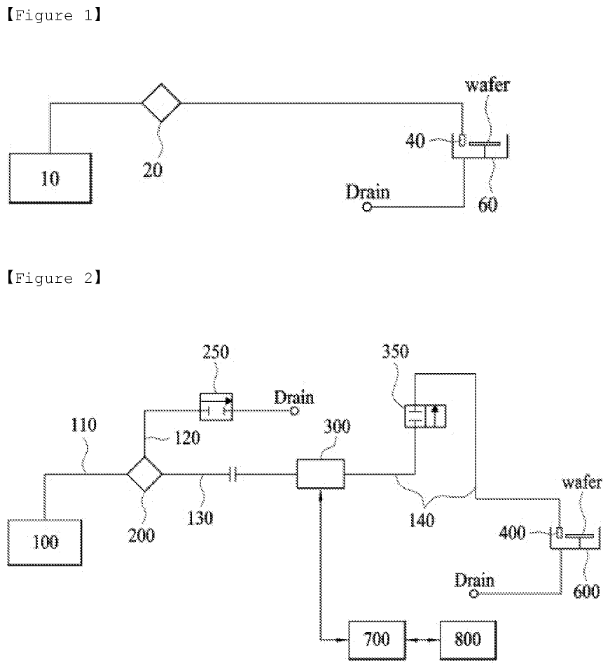

As illustrated in FIG. 2, an apparatus for monitoring particles in a chemical solution according to the present invention includes a chemical solution supply device 100, a particle monitor 300, and a dispenser unit 400. In the embodiment, as the dispenser unit 400, a working nozzle 400 may be used, and hereinafter, it will be described that the working nozzle 400 is used as the dispenser unit 400. However, a specific implementation means of the dispenser unit 40 may be changed in consideration of characteristics of the chemical solution.

Meanwhile, a filter 200 is provided in a first supply channel 110 connecting the chemical solution supply device 100 and the particle monitor 300, and the first supply channel 110 is configured to be branched into a branch channel 120 and a main channel 130 in the filter 290, and the branch channel 120 is connected to a drain valve 250.

In addition, the particle monitor 300 and the working nozzle 400 are connected to each other by a second supply channel 140, and the second supply channel 140 is provided with a control valve 350 capable of opening and closing the second supply channel 140.

The working nozzle 400 supplies the chemical solution on the wafer to perform a semiconductor processing process such as development. The working nozzle 400 is configured to be located in a home position on one side of the wafer in an initial state and move to the upper portion of the wafer when performing a subsequent process to move to the operation position capable of supplying the chemical solution to the wafer.

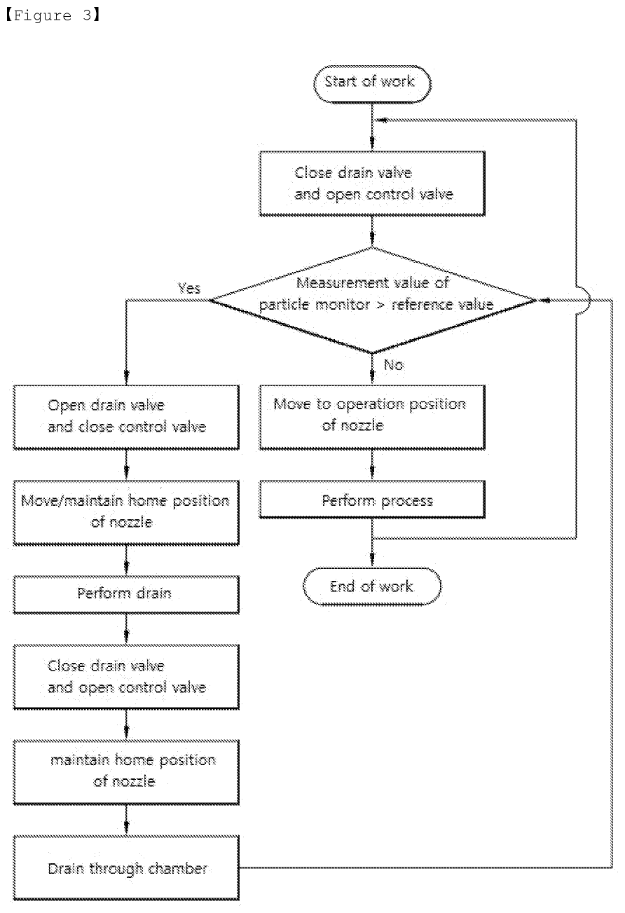

A method for monitoring particles in a chemical solution using the apparatus for monitoring the particles in the chemical solution according to the present invention will be described in detail by using FIG. 3.

First, a work start signal is transmitted to the chemical solution supply device 100 by a control unit (not illustrated) while performing the work, and accordingly, the chemical solution is supplied from the chemical solution supply device 100 to the first supply channel 110.

The chemical solution supply device 100 may be configured to be provided with a pressure pump therein to press and discharge the chemical solution, or the first supply channel 110 may be configured to be provided with a pressing pump to press the chemical solution from the chemical solution supply device 100 and supply the chemical solution to the first supply channel 110.

In the initial working state, the drain valve 250 is in a closed state and the control valve 350 is in an opened state. Accordingly, the chemical solution is supplied to the particle monitor 300 through the filter 200 via the first supply channel 110.

Thereafter, the chemical solution is transmitted to the working nozzle 400 through the control valve 350 that maintains an open state via the particle monitor 300.

The working nozzle 400 moves from the initial home position to a dispensing position on the upper portion of the wafer by the control signal of the control unit according to the start of the wafer processing process by the supply of the chemical solution, and the working nozzle 400 performs the work by supplying the chemical solution on the wafer.

In this process, the particle monitor 300 continuously monitors the particles in the chemical solution to be supplied to the control valve 260 via the main channel 130 to store the value in a server 700 in real time.

The control unit checks whether the monitoring value is less than or equal to a preset value, and if the value is less than or equal to the preset value, the control unit continuously performs the work.

If the monitoring value of the particle monitor 300 is greater than a preset reference value, the control unit closes the control valve 350 and simultaneously moves the working nozzle 400 to the home position.

In addition, the drain valve 250 is opened to drain the solution to be supplied from the chemical solution supply device 100 to the first supply channel 110 to the outside through the branch channel 120.

After the chemical solution is drained through the drain valve 250 for a predetermined time, the drain valve 150 is closed again, and simultaneously, the control valve 350 is opened, so that the chemical solution is supplied to the working nozzle 400 through the particle monitor 300.

At this time, since there is a high possibility that the chemical solution containing the particles remains between the particle monitor 300 and the drain valve 150, the chemical solution flows to the chamber 600 for a predetermined time by maintaining the working nozzle 400 in the home position while the control valve 350 is opened.

The chemical solution discharged from the working nozzle 400 is collected in the chamber 600, and the chemical solution collected in the chamber is configured to be drained to the outside through a drain channel connected to the chamber 600.

In the process of flowing the chemical solution to the chamber 600 for the predetermined time as described above, if a particle detection signal is maintained below a reference value in the particle monitor 300, the working nozzle 400 moves to the operation position to perform the process.

However, if the detection signal of the particle monitor 300 exceeds the reference value again during the draining process, the control valve 350 is closed again, the drain valve 150 is opened, and the chemical solution is drained again for a predetermined time.

As the same process as before, after the chemical solution is drained through the drain valve 250 for a predetermined time, the drain valve 150 is closed again, and simultaneously, the control valve 350 is opened, so that the chemical solution is supplied to the working nozzle 400 through the particle monitor 300.

If the detection signal of the particle monitor 300 is detected to be greater than or equal to a reference value while the working process continues, the process of discharging the particle solution described above proceeds again from the beginning.

Meanwhile, the particle monitor 300 uses a laser scattering method, and is configured to detect the amount of particles by calculating the size and number of scattered light by projecting a laser into the solution.

In addition, the detection signal by the particle monitor 300 is continuously transmitted to the server 700 and stored, and the control unit is configured to check the detection signal transmitted to the server 700 and perform the chemical solution discharge process, and it is preferable that the particle monitor 300 and the server 700 are connected to each other via Bluetooth communication.

Meanwhile, the server 700 is connected to another main server 800 via HSMS communication, and the main server 800 is configured to change parameters of the server 700 by a worker.

The parameters include a reference value for determining that the chemical solution is contaminated in the particle monitor 300, a drain time through the drain valve 150, and a drain time after the control valve 350 is opened.

The parameters are configured to be changed by the user according to the type of chemical solution used in the process.

As described above, the apparatus and the method for monitoring the particles in the chemical solution according to the present invention are configured to monitor the amount of particles contained in the chemical solution in real time and prevent the contamination of the wafer by draining the chemical solution when the amount of particles is greater than or equal to a reference value. Those skilled in the art will be able to understand that the present invention can be easily executed in other detailed forms without changing the technical spirit or an essential feature thereof.

Therefore, it is to be understood that the above-described embodiments are illustrative and not restrictive in all aspects. The scope of the present invention is represented by claims to be described below rather than the detailed description, and it is to be interpreted that the meaning and scope of the claims and all the changed or modified forms derived from the equivalents thereof come within the scope of the present invention.

1. An apparatus for monitoring particles in a chemical solution comprising:
a chemical solution supply device that stores a chemical solution and supplies the chemical solution according to a work start signal of a control unit;
a first supply channel that is connected with the chemical solution supply device to supply the chemical solution;
a filter that is connected with the first supply channel to purify the chemical solution;
a branch channel and a main channel that are branched from the filter;
a drain valve that is connected with the branch channel to open and close the branch channel;
a particle monitor that is connected with the main channel to detect the amount of particles in the chemical solution; and
a dispenser unit that receives the chemical solution from the particle monitor to supply the chemical solution to an object to be worked,
wherein the particle monitor and the dispenser unit are connected to a second supply channel, and
a control valve that controls the supply of the chemical solution to be supplied from the particle monitor to the dispenser unit is included in the second supply channel.

2. The apparatus for monitoring the particles in the chemical solution of claim 1, wherein the control valve blocks or allows the supply of the chemical solution to be supplied from the particle monitor to the dispenser unit.

3. The apparatus for monitoring the particles in the chemical solution of claim 1, wherein when the drain valve is opened, the control valve is closed, and
when the drain valve is in a closed state, the control valve is maintained in an opened state.

4. The apparatus for monitoring the particles in the chemical solution of claim 1, wherein the dispenser unit is selectively movable to a home position which is located on one side of the object to be worked and does not supply the chemical solution to the object to be worked and an operation position which is located on the upper portion of the object to be worked to supply the chemical solution to the object to be worked.

5. The apparatus for monitoring the particles in the chemical solution of claim 4, wherein when a measurement value of the particle monitor is greater than or equal to a preset reference value, the drain valve is opened and the control valve is closed.

6. The apparatus for monitoring the particles in the chemical solution of claim 5, wherein after the chemical solution is drained to the outside through the opened drain valve for a predetermined time, the drain valve is closed and the control valve is opened, and
the dispenser unit moves to the home position, and the chemical solution supplied to the dispenser unit is drained for a predetermined time.

7. The apparatus for monitoring the particles in the chemical solution of claim 6, wherein while the chemical solution is drained through the dispenser unit, when the measurement value of the particle monitor is less than or equal to a reference value, the dispenser unit is moved to the operation position.

8. A method for monitoring particles in a chemical solution using the apparatus for monitoring the particles of claim 1, the method comprising:
a first step of supplying a chemical solution from the chemical solution supply device while a drain valve is closed and a control valve is opened;
a second step of comparing a measurement value measured from the particle monitor with a preset reference value;
a third step of opening the drain valve, closing the control valve, and moving the dispenser unit to a home position when the measurement value is greater than the reference value;
a fourth step of draining the chemical solution through the drain valve for a predetermined time;
a fifth step of closing the drain valve and opening the control valve after the predetermined time;
a sixth step of maintaining the dispenser unit in the home position;
a seventh step of draining the chemical solution through the dispenser unit for a predetermined time; and
an eighth step of performing a process by moving the dispenser unit to an operation position when the measurement value of the particle monitor is maintained less than or equal to the reference value while the seventh step is performed,
wherein in the seventh step or the eighth step, when the measurement value of the particle monitor is greater than the reference value, a next step is performed sequentially from the first step again.
